(19) United States
(12) Patent Application Publication
(10) Pub. No.: US 2019/0326215 A1
(43) Pub. Date: Oct. 24, 2019

(54) METAL EMBEDDED LOW-RESISTANCE BEOL ANTIFUSE

(71) Applicant: International Business Machines Corporation, Armonk, NY (US)

(72) Inventors: Alexander REZNICEK, Troy, NY (US); Chih-Chao YANG, Glenmont, NY (US); Miaomiao WANG, Albany, NY (US)

(21) Appl. No.: 15/956,919

(22) Filed: Apr. 19, 2018

(51) Int. Cl. H01L 23/525; H01L 21/768

(52) U.S. Cl. CPC H01L 23/5252; H01L 21/76805; H01L 21/76831; H01L 21/76886; H01L 21/76847; H01L 21/7684; H01L 21/76879

(57) ABSTRACT

A back-end-of-the-line (BEOL) anti-fuse of a BEOL structure is disclosed. The anti-fuse structure includes a metallization layer formed in a first insulator layer of the BEOL structure. The metallization layer has a trench formed therein. The trench has substantially vertical sidewalls and angled sidewalls formed underlying the vertical sidewalls, the angled sidewalls angled to meet at an apex. The anti-fuse structure further includes a second insulator formed on the vertical sidewalls and the angled sidewalls. The anti-fuse structure further includes a metallic via formed on the second insulator in the trench.

### BACKGROUND

The present invention relates to semiconductor integrated circuit (IC) fabrication, and more specifically, to a process of forming an anti-fuse in an IC metallization layer.

Generally, semiconductor devices include a plurality of circuits that form an integrated circuit (IC) fabricated on a semiconductor substrate. The front-end-of-line (FEOL) is a first portion of IC fabrication where the individual devices (transistors, capacitors, resistors, etc.) are patterned in the semiconductor substrate. FEOL generally covers everything up to (but not including) the deposition of metal interconnect layers. After the last FEOL step, there is a substrate with isolated transistors (without any wires).

The back-end-of-line (BEOL) is the second portion of IC fabrication where the individual devices (transistors, capacitors, resistors, etc.) are interconnected with wiring on the substrate, the wiring referred to as one or more metallization layers or interconnects. Common metals employed for metallization are copper interconnect and aluminum interconnect. BEOL generally begins when a first layer of metal is deposited on the substrate. BEOL includes the fabrication of contacts (pads), interconnect wires, vias, and dielectric structures. For modern IC processing, more than 10 metal layers can be located in the BEOL.

Programmable on-chip anti-fuses are used in many semiconductor integrated circuit applications. Anti-fuses are an important part of a technology offering, as they are used for applications such as memory array redundancy, post-manufacture programming of circuits, and package identification coding. An anti-fuse is an electrical device that performs the opposite function of a fuse. Whereas a fuse initially has a low resistance and is designed to permanently break an electrically conductive path (typically when the current through the path exceeds a specified limit), an anti-fuse initially has a high resistance and is designed to permanently create an electrically conductive path (typically when the voltage across the anti-fuse exceeds a certain level).

In some applications, it is preferable to fabricate on-chip anti-fuses during FEOL transistor device fabrication in order to minimize process cost and improve system integration. The breakdown voltage of conventional planar anti-fuses with a gate dielectric typically employed in the FEOL device fabrication process is too high. Also, planar anti-fuses use too much area compatible with current ground rules of 14 nm, 10 nm or 7 nm technology nodes.

Therefore, there is a need for forming anti-fuses in the BEOL metal interconnect fabrication process.

### SUMMARY

According to one embodiment of the present disclosure, a back-end-of-the-line (BEOL) anti-fuse of a BEOL structure is disclosed. The anti-fuse structure includes a metallization layer formed in a first insulator layer of the BEOL structure. The metallization layer has a trench formed therein. The trench has substantially vertical sidewalls and angled sidewalls formed underlying the vertical sidewalls, the angled sidewalls angled to meet at an apex. The anti-fuse structure further includes a second insulator formed on the vertical sidewalls and the angled sidewalls. The anti-fuse structure further includes a metallic via formed on the second insulator on in the trench.

According to one embodiment of the present disclosure, a method for manufacturing a back-end-of-the-line (BEOL) anti-fuse of a BEOL structure is disclosed. The method includes forming a trench in a metallization layer disposed in a first insulator layer of the BEOL structure, the trench having substantially vertical sidewalls and angled second sidewalls formed underlying the vertical sidewalls, the angled sidewalls angled to meet at an apex. The method further includes forming a second insulator on the vertical sidewalls and the angled sidewalls. The method further includes forming a metallic via formed on the second insulator in the trench.

### BRIEF DESCRIPTION OF THE SEVERAL VIEWS OF THE DRAWINGS

FIG. 1 is a cross-sectional view of an initial BEOL structure.

FIG. 2 is a cross-sectional side view of the BEOL structure of FIG. 1 after performing a dual Damascene patterning process to produce a lower low-k dielectric layer and an upper low-k dielectric layer overlying the dielectric capping layer.

FIG. 3 is a cross-sectional side view of the BEOL structure of FIG. 2 after depositing a liner layer overlying a top portion of the entirety of the upper low-k dielectric layer.

FIG. 4 is a cross-sectional side view of the BEOL structure of FIG. 3 after performing a directional ion bombardment of the liner layer overlying the entirety of the BEOL structure to form a tipped trench in the BEOL structure.

FIG. 5 is a cross-sectional side view of the BEOL structure of FIG. 4 after depositing an anti-fuse insulator layer overlying the entirety of the BEOL structure including the tipped trench.

FIG. 6 is a cross-sectional side view of BEOL structure of FIG. 5 after filling the tipped trench with a metal to form a via.

FIG. 7 is a cross-sectional side view of the final BEOL structure having an anti-fuse structure formed therein, accordance with an embodiment of the present application.

FIG. 8 is a cross-sectional side view of the final BEOL structure having an anti-fuse structure formed therein, wherein the anti-fuse structure is operated to breakdown, accordance with an embodiment of the present application.

### DETAILED DESCRIPTION

Various embodiments provide a BEOL structure, where an anti-fuse is formed directly inside the metal of a BEOL structure. The anti-fuse may be formed from a gouged, almost facetted, metal etch into an underlying copper wire (interconnect), where the anti-fuse element is directly formed in a trench formed in the copper wire. The anti-fuse breaks down inside the copper wire first at a tip of the trench of the copper wire due to there being a higher electric field at a lower voltage (earlier) than a high-k dielectric located on a side wall of the anti-fuse or than a high-k gate dielectric in MOSFET devices. After breakdown, the metal may diffuse in an intervening high-k dielectric (insulator) layer formed between two copper wires and form a conduction path between the two copper wires, leading to a large conduction path that is larger than in typical BEOL anti-fuse structures.

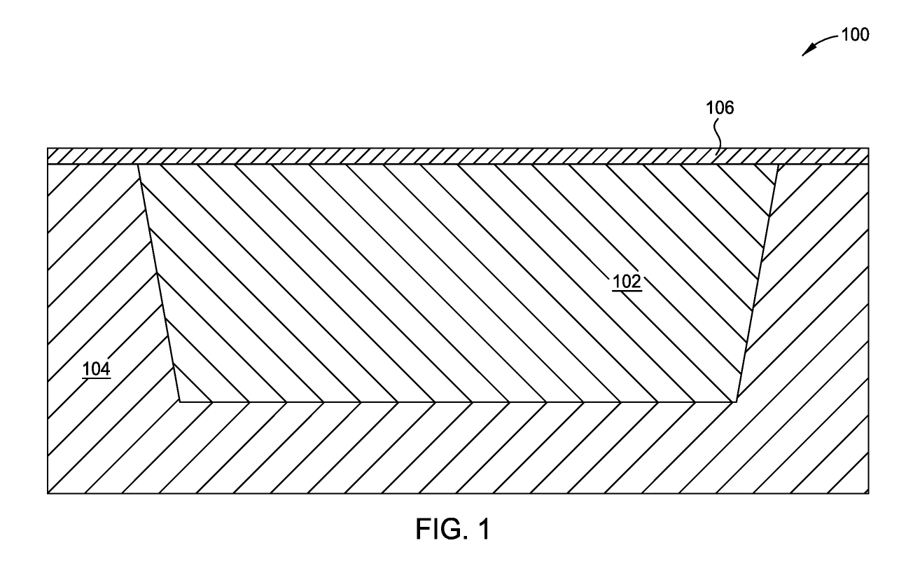

FIG. 1 is a cross-sectional view of an initial BEOL structure 100. The initial BEOL structure 100 includes an existing or a new metallization layer 102 formed therein. The metallization layer 102 may be made of copper (Cu), aluminum (Al), or a Cu—Al alloy. The metallization layer 102 is formed in an insulator layer 104. The insulator layer 104 may be an intra-layer or inter-layer dielectric formed from, for example, a low-k dielectric material (with k<4.0), including but not limited to, silicon oxide, spin-on-glass, a flowable oxide, a high density plasma oxide, borophosphosilicate glass (BPSG), or any combination thereof. For example, the insulator layer may be a dense Ultra-low-k (ULK) dielectric and/or a porous ULK. The insulator layer 104 is deposited by a deposition process, including, but not limited to CVD, PVD, plasma enhanced CVD, atomic layer deposition (ALD), evaporation, chemical solution deposition, or like processes.

The metallization layer 102 may be one of a plurality of metallization layers of the BEOL structure 100 that alternate with intervening dielectric layers 104 that may be interconnected with metal vias (not shown) to an overlying FEOL layer (not shown). In accordance with the present application, each of the metallization layers (not shown) is sandwiched between a lower dielectric layer (not shown) and an upper dielectric layer (not shown). Thus, the BEOL structure 100 includes ‘n’ number of metallization layers, wherein n is at least 1, and n+1 number of dielectric layers; the upper value of ‘n’ may vary and is used to determine the overall thickness of the BEOL structure 100. By way of one example, one layer of dielectric and one layer of metallization are illustrated within the BEOL structure 100. The metallization layer 102 has a first thickness, while the insulator layer 104 has a second thickness that is typically greater than the first thickness, although the second thickness can also be smaller than the first thickness. In one example, the metallization layer 102 may have a thickness from 20 nm to 300 nm, while insulator layer 104 may have a thickness from 20 nm to 400 nm. In one example, ultra low-k dielectric material layer 104 may have a thickness from 50 nm to 1000 nm. Other thicknesses that are lesser than, or greater than, the aforementioned thickness range may also be employed in the present application for the thickness of ultra low-k dielectric material layer 104.

The metallization layer 102 may be formed in the insulator layer 104 using a Damascene or additive patterning process. In Damascene process, an insulator layer 104 is patterned to produce and open trench where the metallization layer 102 is to be disposed therein. A thick coating of copper that significantly overfills the trench is deposited on the insulator layer 104, and chemical-mechanical planarization (CMP) is used to remove the copper (known as overburden) that extends above the top of the insulating layer 104. Copper sunken within the trench of the insulating layer 104 is not removed and becomes the patterned conductor/metallization layer 102.

A dielectric capping layer 106 is deposited on the metallization layer 102 and exposed portions of the insulator layer 104. Non-limiting examples of materials for the dielectric capping layer 106 include NBLoK, silicon carbide, silicon nitride, silicon dioxide, tetraethylorthosilicate (TEOS) oxide, high aspect ratio plasma (HARP) oxide, high temperature oxide (HTO), high density plasma (HDP) oxide, oxides (e.g., silicon oxides) formed by an atomic layer deposition (ALD) process, or any combination thereof. The dielectric capping layer 106 has a thickness in a range from about 30 to about 200 nm, or from about 50 to about 100 nm.

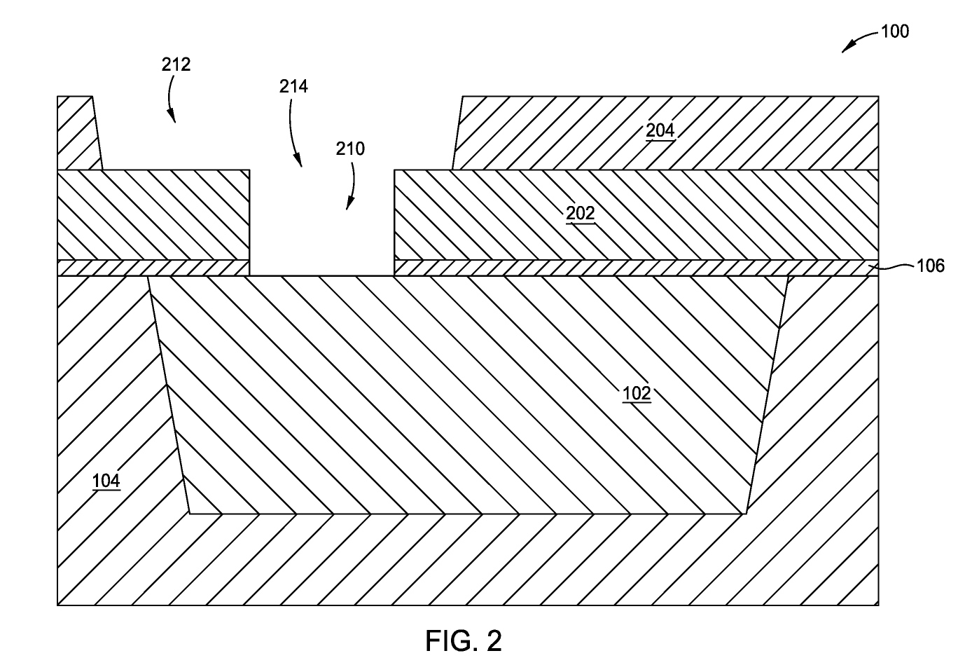

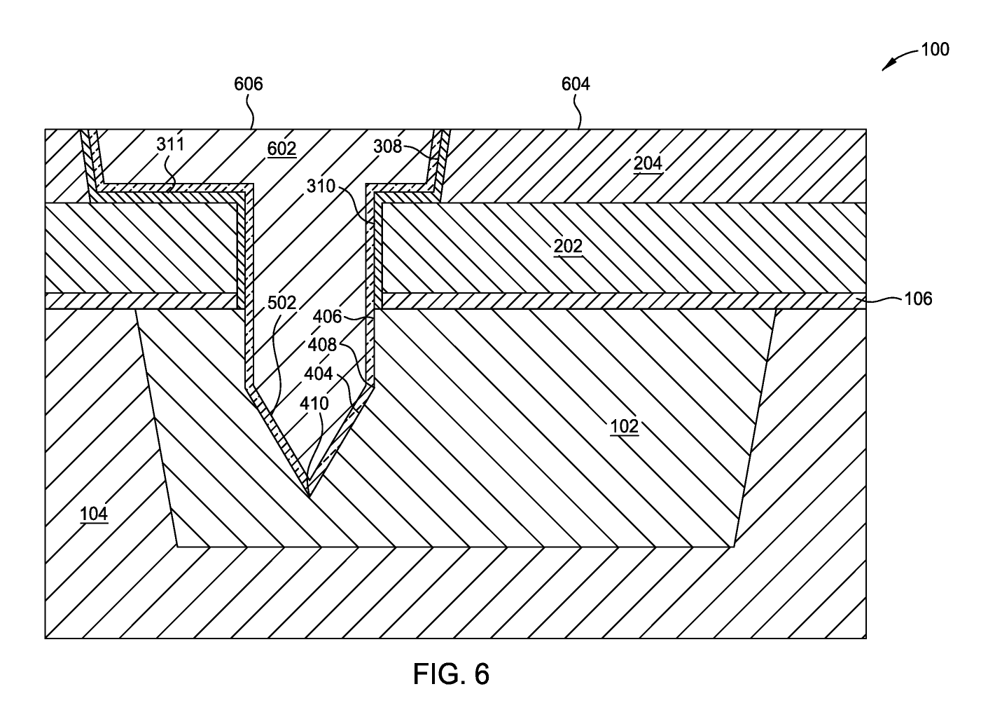

FIG. 2 illustrates the exemplary BEOL structure 100 of FIG. 1 after performing a dual Damascene patterning process to produce a lower low-k dielectric layer 202 and an upper low-k dielectric layer 204 overlying the dielectric capping layer 106. A dual damascene patterning process (DDP) is similar to a single Damascene process, wherein a key difference is “dual”—the DDP creates vias and lines by etching portions 210, 212 of a trench 214 in the dielectric layers 202, 204, and then depositing materials (e.g., copper) in both features, one photo/etch step is employed to form a first portion 210 of the trench 214 in the dielectric layers 202, so as to make connection with underlying metallization layer 102, and a second photo/etch step to make a second portion 212 of the trench 214 in the dielectric layers 204 for a later formed metal via 602 (See FIG. 6).

The DDP forms the first portion 210 of the trench 214 in the lower low-k dielectric layer 202 and the dielectric capping layer 106 selective to the metallization layer 102. The DDP forms the second portion 212 of the trench 214 in the upper low-k dielectric layer 204 that is wider than the first portion 210 of the trench 214. The first portion 210 has a depth from 5 nm to 300 nm and a width from 10 nm to 200 nm. The second portion 212 has a depth from 5 nm to 300 nm and a width from 10 nm to 200 nm.

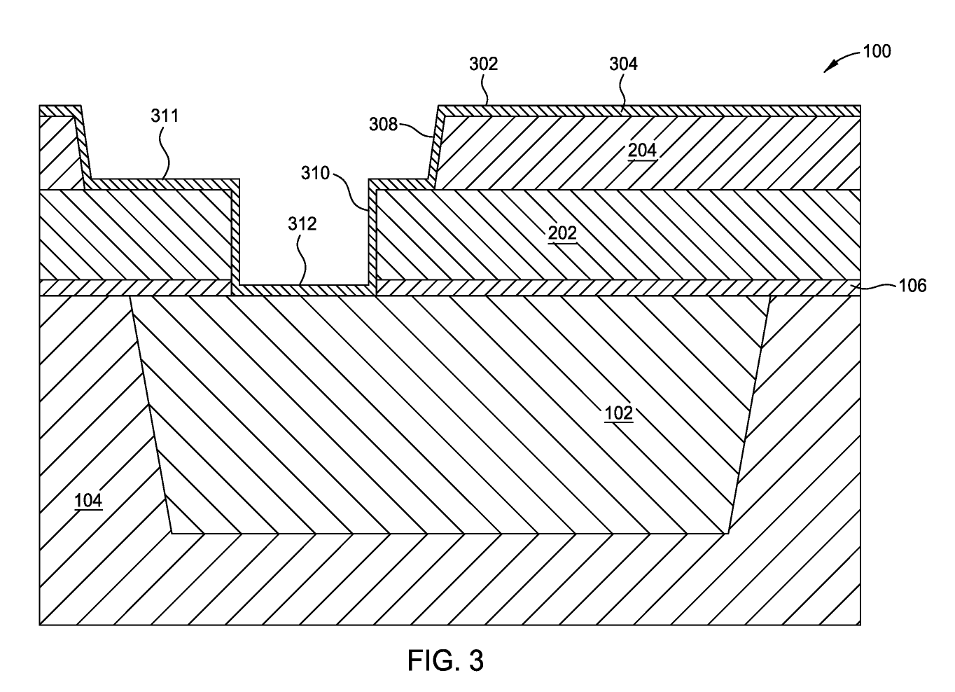

FIG. 3 illustrates the exemplary BEOL structure 100 of FIG. 2 after depositing a liner layer 302 overlying a top portion 304 of the entirety of the upper low-k dielectric layer 204 of the BEOL structure 100. The liner layer 302 is deposited overlying top portions 304 of the upper low-k dielectric layer 204 and side walls 308 of the second portion 212 in the upper low-k dielectric layer 204, the side walls 310 of the first portion 210 in the lower low-k dielectric layer 202, a lip 311 between the sidewalls 308 and the sidewalls 310, and an exposed portion 312 of the metallization layer 102 at the bottom of the trench 214. The liner layer 302 may be either metallic or an insulator. Exemplary materials for the liner layer 302 may be Tantalum (Ta), Tantalum nitride (TaN), Titanium (Ti), Titanium nitride (TiN), Silicon oxide (SiO₂), Silicon nitride (Si₃N₄), silicon carbide (SiC) or combination of the same. The liner layer 302 can be formed by a deposition process including, for example, chemical vapor deposition (CVD), plasma enhanced chemical vapor deposition (PECVD), atomic layer deposition (ALD), physical vapor deposition (PVD), sputtering, chemical solution deposition or plating.

The liner layer 302 acts as a barrier layer to prevent diffusion of copper past the liner layer 302 into overlying materials. In this embodiment, a barrier metal layer completely surrounds all copper interconnections, since diffusion of copper into surrounding materials can degrade their properties. For instance, silicon forms deep-level traps when doped with copper. As the name implies, a barrier metal limits copper diffusivity sufficiently to chemically isolate the copper conductor from the silicon below, yet have high electrical conductivity in order to maintain a good electronic contact. The thickness of the barrier film is also quite important; with too thin a layer, the copper contacts may poison the very devices that they connect to; with too thick a layer, the stack of two barrier metal films and a copper conductor have a greater total resistance than aluminum interconnects, mitigating the benefit.

In one example, the deposited liner layer 302 is thicker in the bottom of the trench 214 than in other deposited locations 306, 308, 310, due to the aspect ratio of the trench portions 210, 212. The thickness of the liner layer 302 at the bottom of the trench 214 is from 4 nm to 70 nm. The thickness of the liner layer 302 in the other deposited locations 306, 308, 310 is from 1 nm to 20 nm.

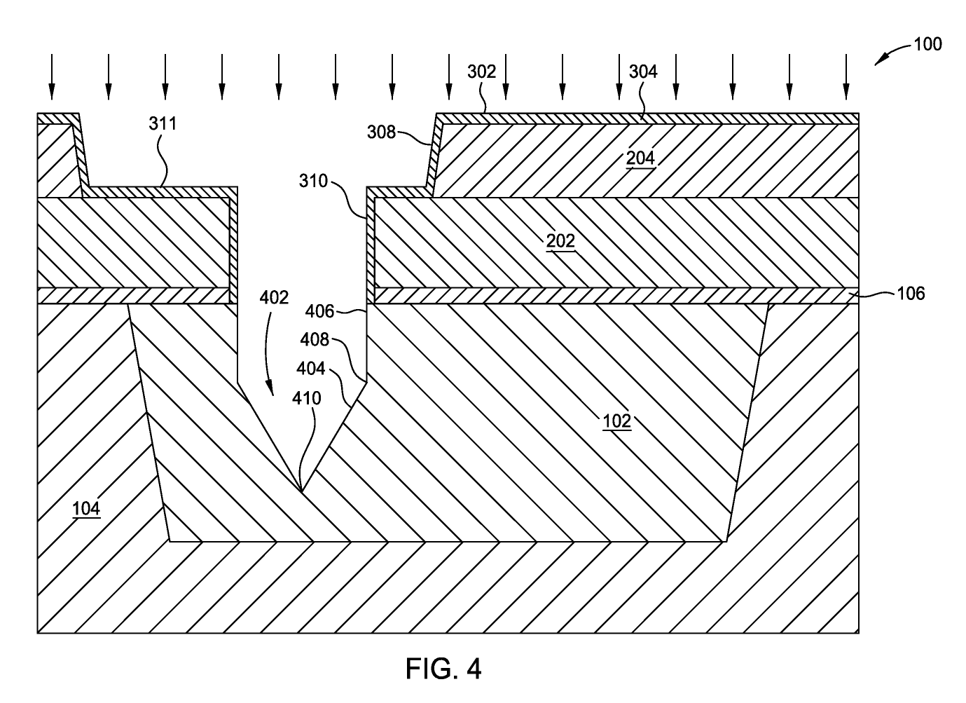

FIG. 4 illustrates the exemplary BEOL structure 100 of FIG. 3 after performing a directional ion bombardment of the liner layer 302 overlying the entirety of the BEOL structure 100 to form a tipped trench 402 in the BEOL structure 100. The ion bombardment may originate from sputtering gases. Exemplary sputtering gases may include Argon, Helium, Krypton, and/or Xenon, or a mixture of the same with H₂. The ion bombardment has the effect of partially removing the liner layer 302 in the deposited locations 306, 308, 310 but has a higher removal rate (>10×) of the liner layer 302 at the bottom of the first portion 210 to expose and partially remove a portion 404 of the metallization layer 102. The higher removal rate of the ion bombardment in the exposed portion 404 of the metallization later 102 causes the formation of the tipped trench 402 that includes the first portion 210, the second portion 212 and the exposed portion 404 of the metallization layer 102. The tipped trench 402 has substantially vertical sidewalls 406 and angled sidewalls 408 formed underlying the vertical sidewalls 406 in the exposed portion 404 of the metallization layer 102. The angled sidewalls 408 are angled inward to meet at an apex 410. The tipped trench 402 has a facetted, triangular shape or cone shape with the apex 410 formed at a lowermost point of the tipped trench 402.

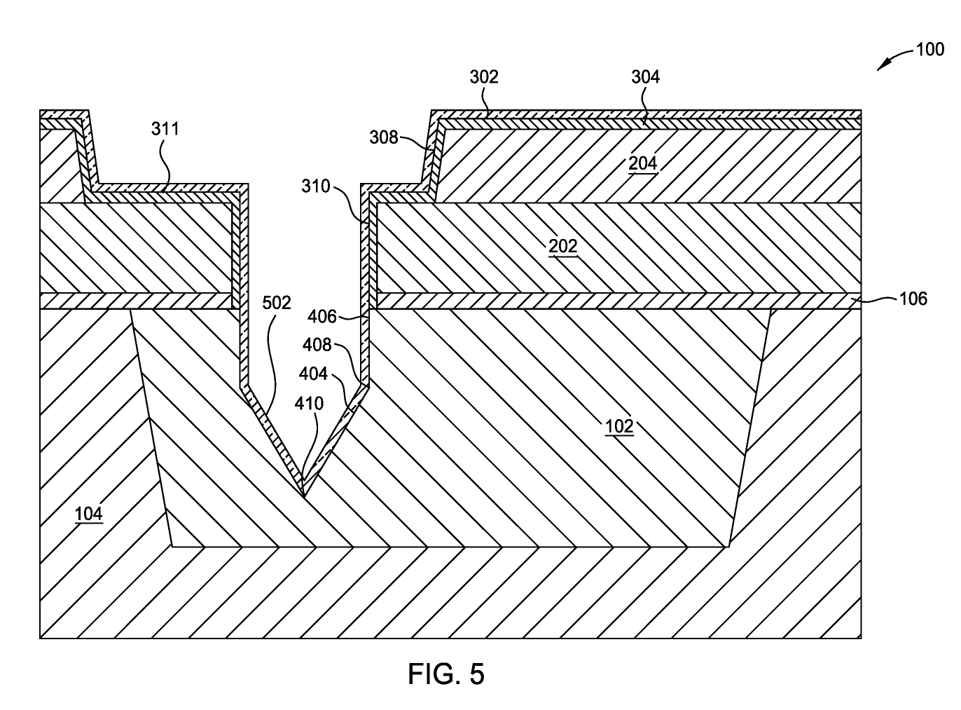

FIG. 5 illustrates the exemplary BEOL structure 100 of FIG. 4 after depositing an anti-fuse insulator layer 502 overlying the entirety of the BEOL structure 100 including the tipped trench 402. The anti-fuse insulator layer 502 is deposited overlying top portions 506 of the BEOL structure 100 and the tipped trench 402 down to the apex 410. The anti-fuse insulator layer 502 may be either a dielectric material, including a high-k dielectric material. The anti-fuse insulator layer 502 can be formed by a deposition process including, for example, chemical vapor deposition (CVD), plasma enhanced chemical vapor deposition (PECVD), atomic layer deposition (ALD), or physical vapor deposition (PVD). The thickness of the anti-fuse insulator layer 502 is from 1 nm to 5 nm.

FIG. 6 illustrates the exemplary BEOL structure 100 of FIG. 5 after filling the tipped trench 402 with a metal to form a via 602. The tipped trench 402 may be filled using an electroplating process. Exemplary metals include copper (Cu), Tungsten (W), Aluminum (Al), Cobalt (Co), or Ruthenium (Ru). After deposition, the via 602 is planarized, by for example, CMP. Any overburden (excess material) exceeding a top portion 604 of the BEOL structure 100 is smoothed to align a top portion 606 of the via 602 metal with the top portion 604 of the BEOL structure 100.

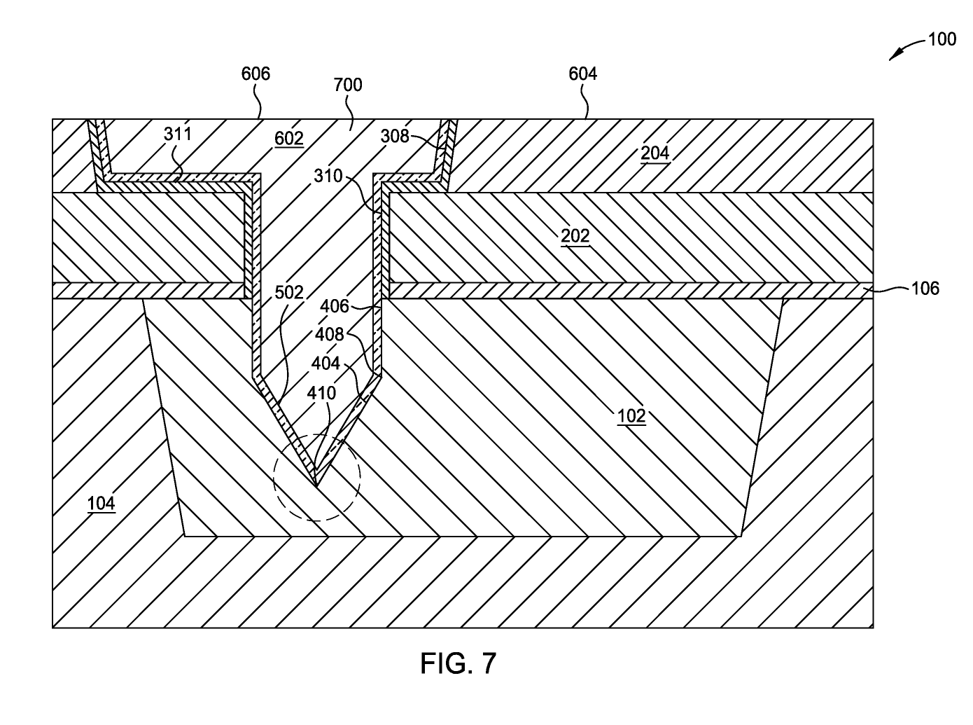

FIG. 7 illustrates the final BEOL structure 100 having an anti-fuse structure 700 formed therein, accordance with an embodiment of the present application. In the illustrated embodiment, the anti-fuse structure 700 includes a metallization layer 102 formed in a first insulator layer 104 of the BEOL structure 100. The metallization layer has a tipped trench 402 formed therein. The tipped trench 402 has substantially vertical sidewalls 406 and angled sidewalls 408 formed underlying the vertical sidewalls 406. The angled sidewalls 408 are angled to meet at an apex 410. An anti-fuse insulator layer 502 is formed overlying the vertical sidewalls 406 and the angled sidewalls 408. A metallic via 602 is formed overlying the anti-fuse insulator layer 502 in the tipped trench 402. The anti-fuse insulator layer 502 underlies the entirety of the metallic via 602.

The anti-fuse insulator layer 502 is made from a high-k material. The metallization layer is made of at least one of copper (Cu), or aluminum (Al). The first insulator layer 104 is made of a low-k material. The metallic via 602 is made of a metal that may include Cu, W, Al, Co, or Ru.

The anti-fuse structure 700 may further include a dielectric capping layer 106 overlying the first insulator layer 104 and a portion of the metallization layer 102 that does not include the tipped trench 402. The anti-fuse structure 700 may further include a lower low-k dielectric layer 202 formed overlying the 106 overlying the first insulator layer 104 and a portion of the meta and an upper low-k dielectric layer 204 formed overlying the lower low-k dielectric layer 202. The anti-fuse structure 700 may further include a liner layer 302 made of a metal that acts as a barrier layer to prevent diffusion of metal from the via 602 past the liner layer 302 into the lower low-k dielectric layer 202 and the upper low-k dielectric layer 204.

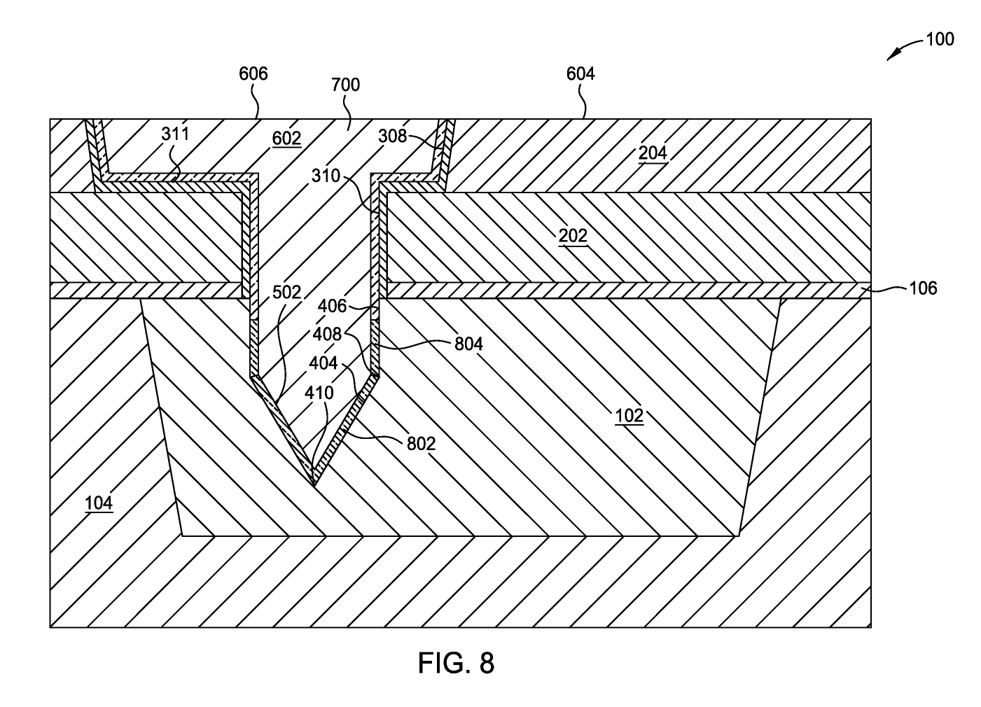

FIG. 8 illustrates the final BEOL structure 100 having an anti-fuse structure 700 formed therein, wherein the anti-fuse structure 700 is operated to breakdown, accordance with an embodiment of the present application. When an appropriate voltage is applied, the anti-fuse structure 700 breakdowns first in a portion 802 of the anti-fuse insulator layer 502 in the vicinity of the apex 410 due to a higher applied electrical field at a lower voltage (earlier) than the anti-fuse insulator layer 502 on its side wall 804 of the anti-fuse structure 700 or than a high-k gate dielectric disposed in overlying MOSFET devices (not shown) located in a FEOL layer (not shown). This results in an anti-fuse structure 700 that has reduced breakdown voltage compared to typical semi-conductor anti-fuses because of electrical field enhancements in the anti-fuse structure 700 due to its triangular-shape. The breakthrough voltage of the anti-fuse structure 700 depends on a thickness of the anti-fuse insulator layer 502 and the applied voltage. The breakthrough voltage for a typical anti-fuse is 2-4 Volts (current design). Related art semiconductor anti-fuses have oxide dielectric materials with a thickness in the range of 10-30 nm, with 20 nm being typical. An anti-fuse manufactured in accordance with embodiments of the present disclosure has a thickness in the range of 1.5-2 nm of high-k instead of low quality oxide. In current device structures having a nominal high-k thickness of 1.5-2 nm, the high-k dielectric breaks down at 2.5 Volts or above.

After breakdown, the metal of the via 602 and the metal of the metallization layer 102 may diffuse into anti-fuse insulator layer 502 and form a conduction path the two metals 602, 102 is formed, which is a larger conduction path than in conventional BEOL anti-fuse structures.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

1. A method for manufacturing a back-end-of-the-line (BEOL) anti-fuse of a BEOL structure, comprising:
forming a trench in a metallization layer disposed in a first insulator layer of the BEOL structure, the trench having vertical sidewalls and angled sidewalls extending from underlying the vertical sidewalls, the angled sidewalls angled to meet at an apex;
forming a second insulator layer on the vertical sidewalls and the angled sidewalls; and
forming a metallic via on the second insulator layer in the trench to form the anti-fuse.

2. The method of claim 1, further comprising, before forming the trench in the metallization layer, forming a dielectric capping layer overlying the first insulator layer and the metallization layer.

3. The method of claim 2, further comprising forming a lower low-k dielectric layer overlying the dielectric capping layer and forming an upper low-k dielectric layer overlying the lower low-k dielectric layer.

4. The method of claim 3, further comprising forming a first portion of a second trench in the lower low-k dielectric layer selective to the metallization layer and a second wider portion of the second trench in the upper low-k dielectric layer overlying the lower low-k dielectric layer.

5. (canceled)

6. The method of claim 4, further comprising forming a liner layer overlying the first portion of the second trench, the second wider portion of the second trench, and the metallization layer underlying the first portion of the second trench.

7. The method of claim 6, wherein the liner layer is made of a metal that acts as a barrier layer to prevent diffusion of metal from the via past the liner layer into the lower low-k dielectric layer and the upper low-k dielectric layer.

8. The method of claim 6, further comprising performing directional ion bombardment with ions of the liner layer to extend the second trench to form the trench in the metallization layer.

9. (canceled)

10. The method of claim 1, wherein the second insulator layer is made of a high-k dielectric material.

11. The method of claim 1, wherein the second insulator layer is formed using a deposition process comprising at least one of chemical vapor deposition (CVD), plasma enhanced chemical vapor deposition (PECVD), atomic layer deposition (ALD), or physical vapor deposition (PVD).

12. The method of claim 1, further comprising performing a planarization process on the via to align a top portion of the via with a top portion of the remainder of the BEOL structure.

13. The method of claim 1, wherein the metallization layer is made of at least one of copper (Cu), aluminum (Al), or a Cu—Al alloy.

14. The method of claim 1, wherein the metallic via is made of a metal selected from the group consisting of copper (Cu), Tungsten (W), Aluminum (Al), Cobalt (Co), or Ruthenium (Ru).

15. A back-end-of-the-line (BEOL) anti-fuse of a BEOL structure, comprising:
a metallization layer formed in a first insulator layer of the BEOL structure, the metallization layer having a trench formed therein, the trench having substantially vertical sidewalls and angled sidewalls formed underlying the vertical sidewalls, the angled sidewalls angled to meet at an apex;
a second insulator formed on the vertical sidewalls and the angled sidewalls; and
a metallic via formed on the second insulator in the trench to produce the anti-fuse.

16. The BEOL anti-fuse of claim 15, wherein the second insulator is made from a high-k material.

17. (canceled)

18. The BEOL anti-fuse of claim 15, wherein the first insulator layer is made of a low-k material.

19. The BEOL anti-fuse of claim 15, wherein the metallic via is made of a metal selected from the group consisting of include.

20. The BEOL anti-fuse of claim 15, wherein the second insulator underlies the entirety of the metallic via.

21. The BEOL anti-fuse of claim 15, further comprising a dielectric capping layer overlying the first insulator layer and a portion of the metallization layer that does not include the trench.

22. The BEOL anti-fuse of claim 21, further comprising a lower low-k dielectric layer formed overlying the dielectric capping layer and an upper low-k dielectric layer formed overlying the lower low-k dielectric layer.

23. The BEOL anti-fuse of claim 22, further comprising a liner layer made of a metal that acts as a barrier layer to prevent diffusion of metal from the via past the liner layer into the lower low-k dielectric layer and the upper low-k dielectric layer.
